(19) United States
(12) Patent Application Publication
(10) Pub. No.: US 2024/0339161 A1
(43) Pub. Date: Oct. 10, 2024

(54) NON-VOLATILE MEMORY DEVICE

(71) Applicant: ROHM CO., LTD., Kyoto (JP)

(72) Inventor: Seiji TAKENAKA, Kyoto (JP)

(21) Appl. No.: 18/749,001

(22) Filed: Jun. 20, 2024

Related U.S. Application Data
(63) Continuation of application No. PCT/JP2022/047120, filed on Dec. 21, 2022.

(30) Foreign Application Priority Data
Dec. 23, 2021 (JP) 2021-208900

(51) Int. Cl. G11C 16/26; G11C 5/14; G11C 16/10

(52) U.S. Cl. CPC G11C 16/26; G11C 5/147; G11C 16/102

(57) ABSTRACT

A non-volatile memory device includes: a first current mirror; a second current mirror; a first resistor portion connected to a first MOS transistor included in the first current mirror; a second resistor portion connected to a second MOS transistor included in the second current mirror; and a sensing portion configured to sense the magnitude relationship between a first current through the first MOS transistor and a second current through the second MOS transistor. The first resistor portion includes a first memory element, which is programmable, and according to whether the first memory element is programmed, the resistance value of the first resistor portion changes.

### CROSS-REFERENCE TO RELATED APPLICATIONS

This nonprovisional application is a continuation application of International Patent Application No. PCT/JP2022/047120 filed on Dec. 21, 2022, which claims priority Japanese Patent Application No. 2021-208900 filed on Dec. 23, 2021, the entire contents of which are hereby incorporated by reference.

### TECHNICAL FIELD

The present disclosure relates to non-volatile memory devices.

### BACKGROUND ART

Non-volatile memories that exploit hot carrier injection into transistors are known. A non-volatile memory of this type includes, as memory elements, a first and a second transistor with paired characteristics in their initial state, and hot carriers are injected into only one of those transistors to change its characteristics. In a read operation thereafter, based on the magnitude relationship between the drain currents of the first and second transistors observed when they are fed with a common gate voltage, whether data corresponding to “0” or data corresponding to “1” is stored in them is read out. For example, a state where the drain current of the first transistor is lower (a state where the characteristics of the first transistor have changed) corresponds to a state where data of “O” is stored, and a state where the drain current of the second transistor is lower (a state where the characteristics of the second transistor have changed) corresponds to a state where data of “1” is stored.

Note that, in the non-volatile memory described above, the stored data (logic value) in the initial state is indefinite. Inconveniently, indefiniteness of the stored data makes it impossible to perform defect inspection at the stage of shipment. To avoid indefiniteness of the stored data in the initial state, some known non-volatile memories are configured such that a higher current passes through, out of the first and second transistors, the second transistor in the initial state. In non-volatile memories of this type, the stored data in the initial state can be fixed to be “0”, and it can be turned to “1” through hot carrier injection into the second transistor. That is, this type of non-volatile memory device permits the setting of “0” as the initial data value.

One example of the known technology mentioned above is seen in Patent Document 1 identified below.

### CITATION LIST

### Patent Literature

Patent Document 1: JP-A-2011-103158

### BRIEF DESCRIPTION OF DRAWINGS

FIG. 1 is a diagram showing the configuration of a non-volatile memory device of a first comparative example.

FIG. 2 is a diagram showing the gate-source voltage dependence of the drain current of a data element;

FIG. 3 is a timing chart showing an example of the waveforms of a signal XRST, the voltage V1 on a line Ln1, and the voltage on a line Ln2.

FIG. 4 is a diagram showing the configuration of a non-volatile memory device of a second comparative example.

FIG. 5 is a diagram showing the configuration of a non-volatile memory device of an embodiment of the present disclosure.

FIG. 6 is a diagram showing characteristics corresponding to a relationship between a gate voltage and the on resistance of a memory element.

FIG. 7 is a diagram showing a more specific implementation for use of the non-volatile memory device of the embodiment shown in FIG. 5.

FIG. 8 is a diagram showing a comparative example of a clamp circuit.

FIG. 9 is a diagram showing the configuration of a non-volatile memory device of a modified example of the present disclosure.

### DESCRIPTION OF EMBODIMENTS

Hereinafter, illustrative embodiments will be described with reference to the accompanying drawings. Any of the non-volatile memory devices described below can be configured as a semiconductor integrated circuit.

### 1. First Comparative Example

Prior to a description of embodiments of the present disclosure, a first comparative example will be described. The description of the first comparative example and a second comparative example, dealt with later, will clarify the significance of the embodiments of the present disclosure.

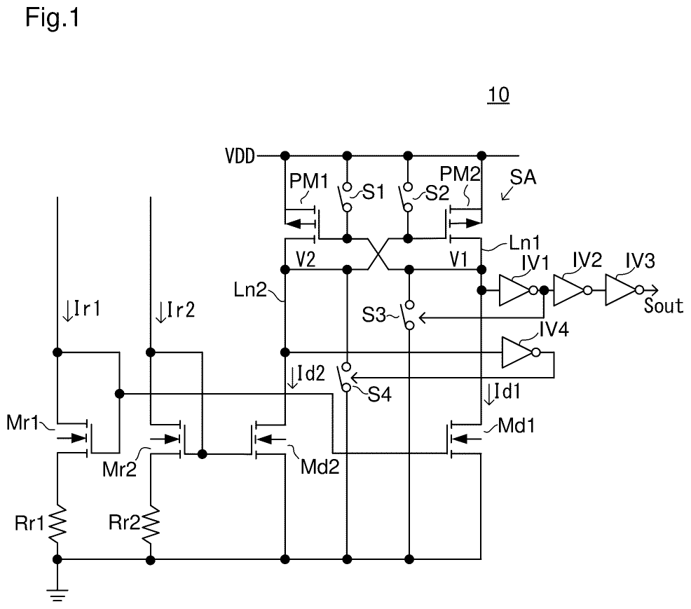

FIG. 1 is a diagram showing the configuration of a non-volatile memory device 10 of the first comparative example. The non-volatile memory device 10 is a circuit for storing one-bit data, and includes a first reference element Mr1, a second reference element Mr2, a first reference resistor Rr1, a second reference resistor Rr2, a first data element Md1, a second data element Md2, and a sense amplifier SA.

The combination of the first and second data elements Md1 and Md2 permits the storage of data of “0” or data of “1”.

The data elements Md1 and Md2 and the reference elements Mr1 and Mr2 are all configured as memory elements, and are configured, more specifically, with NMOS transistors (N-channel MOSFETs [metal-oxide-semiconductor field-effect transistors]). A memory element is an element that can change the characteristics of a transistor through hot carrier injection and thereby execute a program operation, and is also called an OTP (one-time programmable) element.

The gate and the drain of the first reference element Mr1 are short-circuited together. The source of the first reference element Mr1 is connected to one terminal of the first reference resistor Rr1. The other terminal of the first reference resistor Rr1 is connected to a ground terminal (an application terminal for a ground potential).

The gate of the first data element Md1 is connected to the gate of the first reference element Mr1. The source of the first data element Md1 is connected to the ground terminal. The drain of the first data element Md1 is connected to one input terminal of the sense amplifier SA.

The gate and the drain of the second reference element Mr2 is short-circuited together. The source of the second reference element Mr2 is connected to one terminal of the second reference resistor Rr2. The other terminal of the second reference resistor Rr2 is connected to the ground terminal.

The gate of the second data element Md2 is connected to the gate of the second reference element Mr2. The source of the second data element Md2 is connected to the ground terminal. The drain of the second data element Md2 is connected to the other input terminal of the sense amplifier SA.

Thus, the first reference element Mr1 and the first data element Md1 constitute a current mirror, and so do the second reference element Mr2 and the second data element Md2.

The first and second reference resistors Rr1 and Rr2 have the same resistance value. The data elements Md1 and Md2 and the reference elements Mr1 and Mr2 have the same structure, and have the same electrical characteristics before execution of the program operation. The target of the program operation is the data elements Md1 and Md2. Accordingly, before execution of the program operation, the data elements Md1 and Md2 and the reference elements Mr1 and Mr2 have the same gate threshold voltage. Thus, before execution of the program operation, the drain currents through the data elements Md1 and Md2 and the drain currents through the reference elements Mr1 and Mr2 are in a magnitude relationship such that Id1>Ir1 and Id2>Ir2. Moreover, Ir1=Ir2, and hence Id1=Id2. Thus, there is no difference between the currents through the data elements Md1 and Md2 and this results in indefinite data. That is, in the non-volatile memory device 10 of this configuration, with no program operation executed for the data elements Md1 and Md2, no initial data value is set.

Here, when “structure” is mentioned with respect to a transistor, it covers the size of the transistor. Accordingly, when a plurality of transistors are mentioned to have the same structure, it means that they have the same size. If a plurality of transistors have the same structure, with no program operation and hence no hot carrier injection performed for any of them, those transistors have the same electrical characteristics (including gate threshold voltage). It should however be noted that, when a plurality of transistors are mentioned to have the same structure and the same electrical characteristics, it means that they do so by design and, in reality, allow for errors (that is, “same” should be understood not to exclude errors).

The non-volatile memory device 10 can execute a read operation for reading out the data stored in the data elements Md1 and Md2 and the program operation (write operation) for overwriting the data (logic value) stored in the data elements Md1 and Md2.

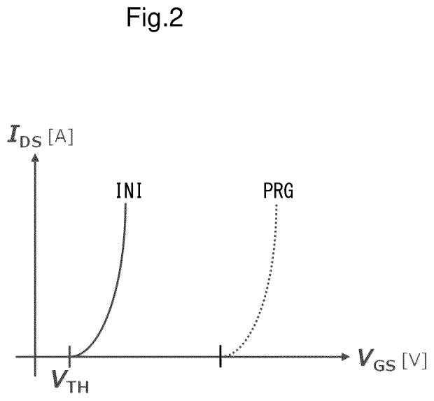

The program operation is carried out by a programming circuit (unillustrated). In the program operation, the programming circuit injects hot carriers into the data elements Md1 and Md2 and thereby changes the electrical characteristics of the data elements Md1 and Md2. This change raises the gate threshold voltage of the data elements Md1 and Md2. In FIG. 2, a solid-line waveform INI represents the gate-source voltage dependence of the drain currents through the data elements Md1 and Md2 before execution of the program operation, and a broken-line waveform PRG represents the gate-source voltage dependence of the drain currents through the data elements Md1 and Md2 after execution of the program operation. In this way, the program operation raises the gate threshold voltage Vth.

The program operation is executed, for example, by applying a supply voltage VDD to the gates of the data elements Md1 and Md2, VDD to their sources, and a ground potential (0 V) to their drains.

While the drain currents Ir1 and Ir2 are being supplied, the sense amplifier SA outputs, in the read operation, an output signal Sout corresponding to the value (logic value) of the stored data based on the magnitude relationship between the drain currents Id1 and Id2 through the data elements Md1 and Md2

Injecting hot carriers into, of the data elements Md1 and Md2 before execution of the program operation, the first data element Md1 results in the gate threshold voltage of the first data element Md1 being raised. Thus, after execution of the program operation, the gate threshold voltage of the first data element Md1 is higher than the gate threshold voltage of the second data element Md2. Hence, the drain currents Id1 and Id2 have a magnitude relationship such that Id1<Id2. The state where the drain current Id1 is lower than the drain current Id2 corresponds to the state where data of “0” is stored. Thus, in the read operation, if the drain current Id1 is lower than the drain current Id2, the sense amplifier SA outputs an output signal Sout corresponding to data of “0” (i.e., a low-level Sout).

By contrast, injecting hot carriers into, of the data elements Md1 and Md2 before execution of the program operation, the second data element Md2 results in the gate threshold voltage of the second data element Md2 being raised. Thus, after execution of the program operation, the gate threshold voltage of the second data element Md2 is higher than the gate threshold voltage of the first data element Md1. Hence, the drain currents Id1 and Id2 have a magnitude relationship such that Id1>Id2. The state where the drain current Id1 is higher than the drain current Id2 corresponds to the state where data of “1” is stored. Thus, in the read operation, if the drain current Id1 is higher than the drain current Id2, the sense amplifier SA outputs an output signal Sout corresponding to data of “1” (i.e., a high-level Sout).

As shown in FIG. 1, the sense amplifier SA includes PMOS transistors (P-channel MOSFETs) PM1 and PM2, switches S1 and S2, switches S3 and S4, and inverters IV1 to IV4.

The source of the PMOS transistor PM2 is connected to an application terminal for the supply voltage VDD. The drain of the PMOS transistor PM2 is connected to a line Ln1. The gate of the PMOS transistor PM2 is connected to a line Ln2. The line Ln1 is connected to the drain of the first data element Md1. The line Ln2 is connected to the drain of the second data element Md2.

The source of the PMOS transistor PM1 is connected to the application terminal for the supply voltage VDD. The drain of the PMOS transistor PM1 is connected to the line Ln2. The gate of the PMOS transistor PM1 is connected to the line Ln1.

Between the application terminal for the supply voltage VDD and the line Ln1, the switch S1 is connected. Between the application terminal for the supply voltage VDD and the line Ln2, the switch S2 is connected.

The input terminal of the inverter IV1 is connected to the line Ln1. The output terminal of the inverter IV1 is connected to the input terminal of the inverter IV2. The output terminal of the inverter IV2 is connected to the input terminal of the inverter IV3. The inverter IV3 outputs the output signal Sout.

Between the line Ln1 and the ground terminal, the switch S3 is connected. According to the output of the inverter IV1, the switch S3 is turned on and off. Between the line Ln2 and the ground terminal, the switch S4 is connected. The input terminal of the inverter IV4 is connected to the line Ln2. According to the output of the inverter IV4, the switch S4 is turned on an off.

A control circuit (unillustrated) can output a signal XRST and turns the switches S1 and S2 on and off.

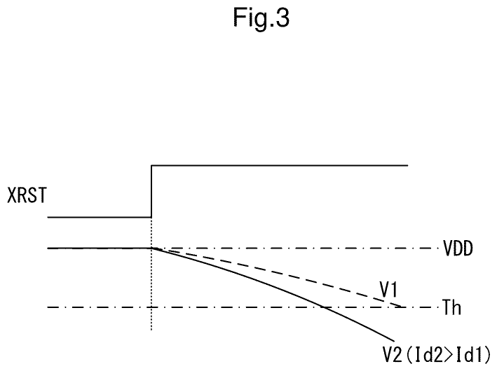

FIG. 3 is a timing chart showing an example of the waveforms of the signal XRST, the voltage V1 on the line Ln1, and the voltage V2 on the line Ln2. With reference additionally to FIG. 3, the operation of the sense amplifier SA will be described. In the read operation, a period in which the signal XRST is at low level is referred to as the pre-charge period and a period in which the signal XRST is at high level is referred to as the read period.

In the pre-charge period, in which the signal XRST is at low level, the drain currents Ir1 and Ir2 are off and the switches S1 and S2 are on. Thus, the gate and the source of the PMOS transistors PM1 and PM2 are short-circuited together, so that the PMOS transistors PM1 and PM2 are off. Through the switch S1, which is on, a positive charge is supplied to the line Ln1, and the voltage V1 reaches the level of the supply voltage VDD. Through the switch S2, which is on, a positive charge is supplied to the line Ln2, and the voltage V2 too reaches the level of the supply voltage VDD. In this state, the outputs of the inverters IV1 and IV4 are at low level, so that the switches S3 and S4 are off.

When the signal XRST is switched from low level and high level and a transition from the pre-charge period to the read period takes place, the drain currents Ir1 and Ir2 are turned on and the switches S1 and S2 are turned off. Thus, the drain current Id2 passes, causing the voltage V2 to fall, and the drain current Id1 passes, causing the voltage V1 to fall.

In the read operation after execution of the program operation for the first data element Md1, Id2>Id1; thus, the voltage V2 falls faster than the voltage V1 (FIG. 3, “V2 (Id2>Id1)”). When the voltage V2 reaches the threshold value Th earlier than the voltage V1, the output of the inverter IV4 switches from low level to high level and the switch S4 is turned on. This results in V2=0V, so that the PMOS transistor PM2 is on and the voltage V1 equals VDD. In this state, the PMOS transistor PM1 is off.

Accordingly, the output signal Sout output from the inverter IV3 is at low level. That is, the output signal Sout is output as a signal that indicates the state where “0” is stored.

By contrast, in the read operation after execution of the program operation for the second data element Md2, Id2<Id1; thus, the voltage V1 falls faster than the voltage V2. When the voltage V1 reaches the threshold value Th earlier than the voltage V2, the output of the inverter IV1 switches from low level to high level and the switch S3 is turned on. This results in V1=0V, so that the PMOS transistor PM1 is on and the voltage V2 equals VDD. In this state, the PMOS transistor PM2 is off. Accordingly, the output signal Sout output from the inverter IV3 is at high level. That is, the output signal Sout is output as a signal that indicates the state where “1” is stored.

### 2. Second Comparative Example

As described above, in the non-volatile memory device 10 of the first comparative example, while there is no initial data value, executing the program operation for one of the data elements Md1 and Md2 permits storage of data. However, in some cases, the availability of an initial data value is preferred, and so a description will now be given of a second comparative example as one example of a configuration that permits the setting of an initial value.

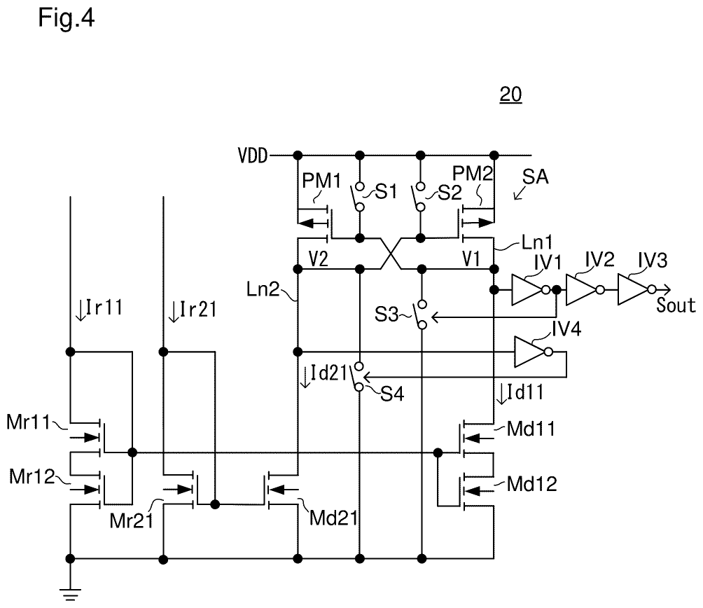

FIG. 4 is a diagram showing the configuration of a non-volatile memory device 20 of the second comparative example. The non-volatile memory device 20 includes reference elements Mr11 and Mr12, a reference element Mr21, data elements Md11 and Md12, a data element Md21, and a sense amplifier SA.

The reference elements Mr11 and Mr12, the reference element Mr21, the data elements Md11 and Md12, and the data element Md21 are all configured with NMOS transistors, and are memory elements (OTP elements).

The source of the reference element Mr11 is connected to the drain of the reference element Mr12. The source of the reference element Mr12 is connected to a ground terminal. The gates of the reference elements Mr1l and Mr12 are short-circuited to the drain of the reference element Mr11. The source of the data element Md11 is connected to the drain of the data element Md12. The source of the data element Md12 is connected to the ground terminal. The gates of the data elements Md11 and Md12 are connected to the gates of the reference elements Mr11 and Mr12. The drain of the data element Md11 is connected to a line Ln1. With this configuration, the reference elements Mr11 and Mr12 and the data elements Md11 and Md12 constitute a current mirror. The drain current Ir11 through the reference elements Mr11 and Mr12 is mirrored to produce the drain current Id11 through the data elements Md11 and Md12.

The gate and the drain of the reference element Mr21 are short-circuited together. The source of the reference element Mr21 is connected to the ground terminal. The gate of the data element Md21 is connected to the gate of the reference element Mr21. The source of the data element Md21 is connected to the ground terminal. The drain of the data element Md21 is connected to a line Ln2. With this configuration, the reference element Mr21 and the data element Md21 constitute a current mirror. The drain current Ir21 through the reference element Mr21 is mirrored to produce the drain current Id21 through the data element Md21.

The data elements Md11 and Md12 and the reference elements Mr1l and Mr12 have the same structure and, before execution of the program operation, have the same electrical characteristics. Note that the data elements Md11 and Md12 are not the target of the program operation.

The data element Md21 and the reference element Mr21 have the same structure and, before execution of the program operation, have the same electrical characteristics. The target of the program operation is the data element Md21.

The gate width w2 of the data element Md21 and the reference element Mr21 is twice the gate width w1 of the data elements Md11 and Md12 and the reference elements Mr11 and Mr12. Thus, the on resistance of the reference element Mr21 is one-fourth of the on resistance of the circuit comprising the reference elements Mr1l and Mr12, and the on resistance of the data element Md21 is one-fourth of the circuit comprising the data elements Md11 and Md12.

Thus, with the data element Md21 in a state before execution of the program operation, if the ratio of the drain current Ir11 through the reference elements Mr11 and Mr12 to the drain current Ir21 through the reference element Mr21 is such that Ir11:Ir21=1:4, then the ratio of the drain current Id11 through the data elements Md11 and Md12 to the drain current Id21 through the data element Md21 is such that Id11:Id21=1:4.

Accordingly, in the read operation in which, after pre-charging in the sense amplifier SA, the drain currents Ir11 and Ir12 are supplied, Id21>Id11, and the sense amplifier SA outputs an output signal Sout corresponding to data of “0” (i.e., a low-level Sout).

By contrast, in the read operation in a state after execution of the program operation in the data element Md21, Id21<Id11, and the sense amplifier SA outputs an output signal Sout corresponding to data of “1” (i.e., a high-level Sout).

As described above, in this comparative example, in a state where no program operation has been executed in the data element Md21, data of “0” can be set as an initial value. However, this comparative example is configured to presuppose, for the mirroring of currents, well-paired characteristics between the data elements Md11 and Md12 and the reference elements Mr11 and Mr12 and between the data element Md21 and the reference element Mr21.

Here, using programmably configured memory elements (OTP elements) as reference elements and data elements, as compared with using ordinary MOS transistors, results in the data elements (adjacent elements) exhibiting greater variations with respect to the reference elements. Thus, the paired characteristics mentioned above may affect the mirroring of currents and hence affect the state of the initial value.

### 3. Embodiments of the Present Disclosure

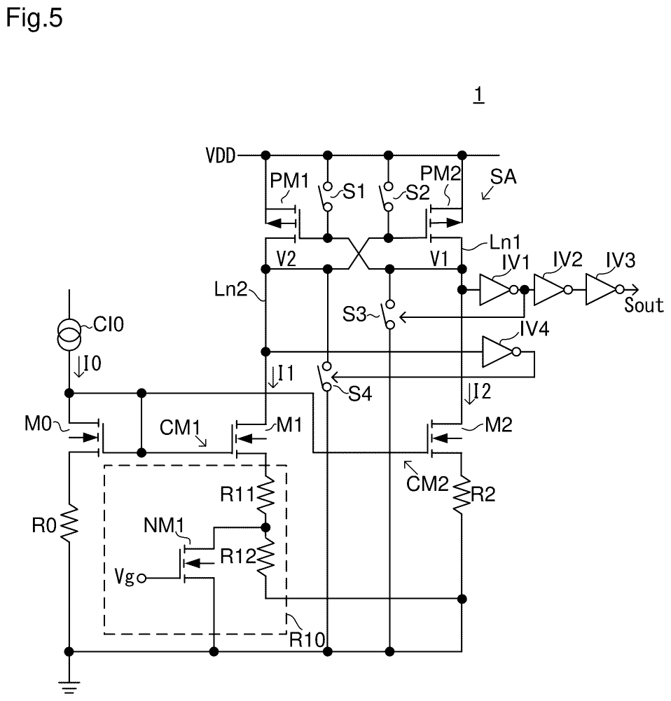

To address the problems discussed above, an embodiment of the present disclosure is devised. Now, the embodiment of the present disclosure will be described. FIG. 5 is a diagram showing the configuration of a non-volatile memory device 1 of the embodiment of the present disclosure.

The non-volatile memory device 1 includes a constant current source CI0, transistors M0, M1, and M2, a resistor element R0, resistor elements R11, R12, and R2, a memory element NM1, and a sense amplifier SA.

The transistors M0, M1, and M2 are all configured as NMOS transistors. The drain of the transistor M0 is connected to the constant current source CI0. The gate and the drain of the transistor M0 are short-circuited together. The source of the transistor M0 is connected to one terminal of the resistor element R0. The other terminal of the resistor element R0 is connected to a ground terminal. The gate of the transistor M2 is connected to the gate of the transistor M0. The source of the transistor M2 is connected to one terminal of the resistor element R2. The other terminal of the resistor element R2 is connected to the ground terminal. The drain of the transistor M2 is connected to a line Ln1. The transistors M0 and M2 constitute a current mirror CM2.

The gate of the transistor M1 is connected to the gate of the transistor M0. The source of the transistor M1 is connected to one terminal of the resistor element R11. The other terminal of the resistor element R11 is connected to one terminal of the resistor element R12. The other terminal of the resistor element R12 is connected to the other terminal of the resistor element R2.

The memory element (OTP element) NM1 is configured with an NMOS transistor, and is configured to be programmable. A node to which the resistor elements R11 and R12 are connected is connected to the drain of the memory element NM1. The source of the memory element NM1 is connected to the ground terminal. The resistor elements R11 and R12 and the memory element NM1 constitute a resistor portion R10. One terminal of the resistor portion R10 is connected to the source of the transistor M1. The other terminal of the resistor portion R10 is connected to the ground terminal. The drain of the transistor M1 is connected to a line Ln2. The transistors M0 and M1 constitute a current mirror CM1.

The transistors M0, M1, and M2 have the same structure, and have the same electrical characteristics. In a state before execution of the program operation in the memory element NM1, the gate threshold voltage Vth of the memory element NM1 is low and the on resistance of the memory element NM1 as it is when a gate voltage Vg is applied to its gate is low. This corresponds to a state where the memory element NM1 acting as a switch is on. The resistance value of the resistor portion R10 is the combined resistance value of the circuit comprising the resistor element R12 and the memory element NM1 connected in parallel with each other and plus the resistor element R11 connected in series with them. Accordingly, in a state before execution of the program operation in the memory element NM1, the resistance value of the resistor portion R10 is lower than the resistance value of the resistor element R2.

Thus, in the read operation in a state where, after pre-charging in the sense amplifier SA, a constant current I0 is supplied from the constant current source CI0, the drain current I1 through the transistor M1 and the drain current I2 through the transistor M2 are such that I1>I2, and the sense amplifier SA outputs an output signal Sout corresponding to data of “0” (i.e., a low-level Sout).

By contrast, in a state after execution of the program operation in the memory element NM1, the gate threshold voltage Vth of the memory element NM1 is high and the on resistance of the memory element NM1 as it is when the gate voltage Vg is applied to its gate is high. This corresponds to a state where the memory element NM1 acting as a switch is off. Accordingly, in a state after execution of the program operation in the memory element NM1, the resistance value of the resistor portion R10 is higher than the resistance value of the resistor element R2.

Thus, in the read operation in a state where, after pre-charging in the sense amplifier SA, the constant current I0 is supplied from the constant current source CI0, the drain current I1 through the transistor M1 and the drain current I2 through the transistor M2 are such that I1<I2, and the sense amplifier SA outputs an output signal Sout corresponding to data of “1” (i.e., a high-level Sout).

As described above, in this embodiment, in a state where no program operation has been executed in the memory element NM1, an initial data value can be set based on the difference between the resistance values of the resistor portion R10 and the resistor element R2. In particular, in this embodiment, the disuse of reference elements as memory elements eliminates the need to give consideration to paired characteristics of memory elements; what is needed is just to specify the gate voltage Vg in absolute value. This helps reduce the effect on the state of the initial value. Moreover, owing to the transistors M0, M1, and M2 being ordinary MOS transistors unlike memory elements, well-paired characteristics are easy to achieve.

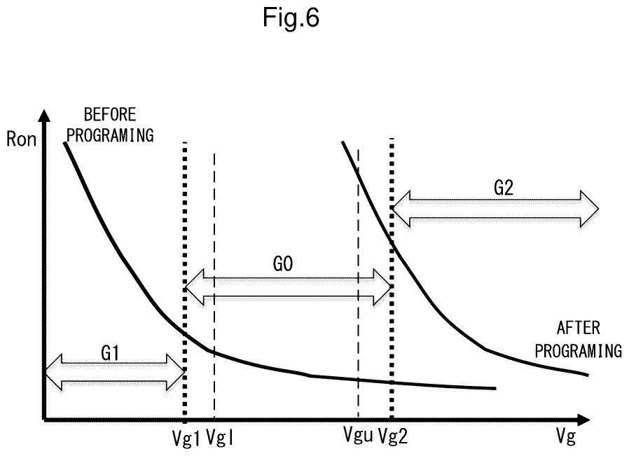

FIG. 6 is a diagram showing the characteristics corresponding to the relationship between the gate voltage Vg and the on resistance Ron of the memory element NM1, comparing them between before and after execution of the program operation in the memory element NM1. Before execution of the program operation, in a region G1 where the gate voltage Vg is lower than a first predetermined voltage Vg1, the on resistance Ron is too high. On the other hand, after execution of the program operation, in a region G2 where the gate voltage Vg is higher than a second predetermined voltage Vg2, the on resistance Ron is too low. Thus, the range G0 between the first predetermined voltage Vg1 and the second predetermined voltage Vg2, both ends inclusive, is the range of an appropriate gate voltage Vg. In this embodiment, the gate voltage Vg used in the read operation is limited within the range G0.

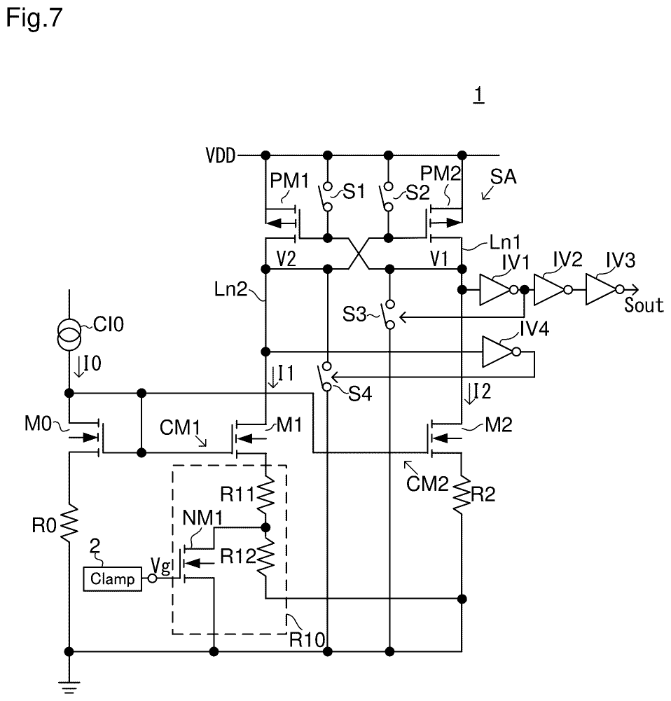

FIG. 7 is a diagram showing a more specific implementation for use of the non-volatile memory device 1 of the embodiment shown in FIG. 5. As shown in FIG. 7, the memory element NM1 has a clamp circuit 2 connected to its gate.

In this embodiment, when the supply voltage VDD starts up and rises from 0 V, the gate voltage Vg rises. Meanwhile the constant current source CI0 is off and the constant current I0 is not supplied. While the gate voltage Vg is within the region G1, the sense amplifier SA performs pre-charging and completes it (with the switches S1 and S2 turned off). After that, when the gate voltage Vg rises until it reaches a predetermined lower-limit voltage Vg1 (FIG. 6) that falls within the range G0, the constant current source CI0 is turned on and the constant current I0 starts to be supplied. As a result, the drain currents I1 and I2 pass and the read operation is executed.

In this way, only when at the start-up of the supply voltage VDD the gate voltage Vg reaches the lower-limit voltage Vg1 are the drain currents I1 and I2 supplied. This makes it possible to execute the read operation with an appropriate value in the on resistance Ron of the memory element NM1.

On the other hand, in this embodiment, owing to the provision of the clamp circuit 2, even if the gate voltage Vg tends to exceed a predetermined upper-limit voltage Vgu (FIG. 6) that falls within the range G0, the gate voltage Vg can be clamped at the upper-limit voltage Vgu. This prevents the gate voltage Vg from exceeding the upper-limit voltage Vgu and makes it possible to execute the read operation with an appropriate value in the on resistance Ron of the memory element NM1.

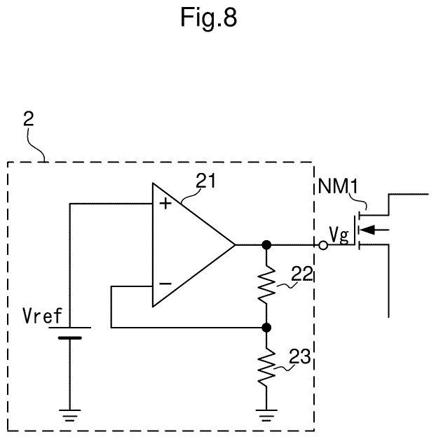

FIG. 8 is a diagram showing a configuration example of the clamp circuit 2. The clamp circuit 2 shown in FIG. 8 includes an amplifier 21 and voltage division resistors 22 and 23. To the non-inverting input terminal (+) of the amplifier 21 is connected an application terminal for a reference voltage Vref. The output terminal of the amplifier 21 is connected to the gate of the memory element NM1 and to one terminal of the voltage division resistor 22. The other terminal of the voltage division resistor 22 is connected to one terminal of the voltage division resistor 23. The other terminal of the voltage division resistor 23 is connected to a ground terminal. The node to which the voltage division resistors 22 and 23 are connected is connected to the inverting input terminal (−) of the amplifier 21. Thus, the gate voltage Vg is clamped at the reference voltage Vref (upper-limit voltage Vgu).

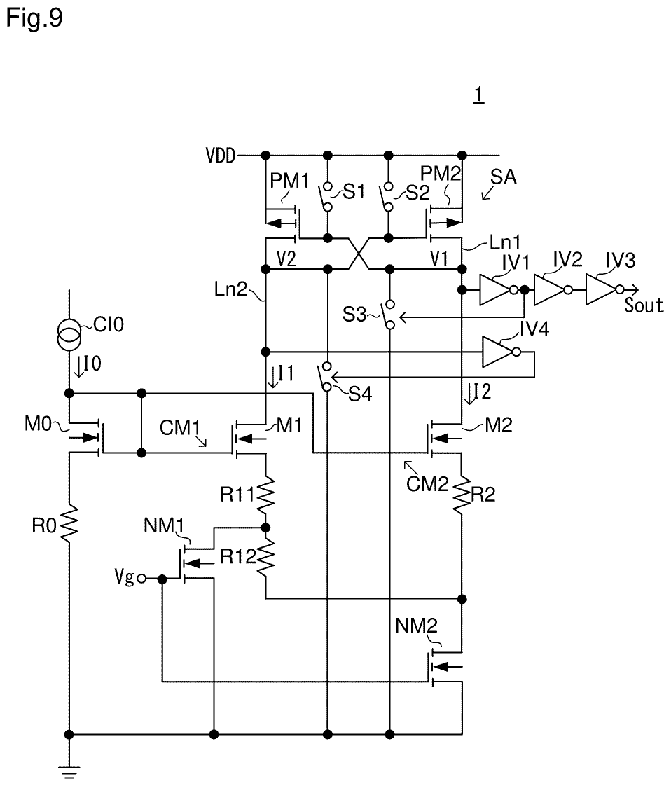

FIG. 9 is a diagram showing a non-volatile memory device 1 of a modified example of the present disclosure. The non-volatile memory device 1 shown in FIG. 9 includes a memory element NM2. The memory element NM2 is configured with an NMOS transistor, and is used with no program operation executed. The drain of the memory element NM2 is connected to the node to which the resistor elements R12 and R2 are connected. The source of the memory element NM2 is connected to the ground terminal. The gate of the memory element NM2 is connected to the gate of the memory element NM1 and can be fed with the gate voltage Vg.

With this configuration, when at the start-up of the supply voltage VDD the gate voltage Vg rises until it reaches the lower-limit voltage Vg1 (FIG. 6), the memory element NM2 turns on and the drain currents I1 and I2 pass. This makes it possible to execute the read operation with an appropriate value in the on resistance Ron of the memory element NM1.

In a case where a plurality of devices each implemented with the configuration shown in FIG. 9 are used, the resistor elements R12 and R2 in all those devices can be connected to the drain of one memory element NM2. It is thus possible to share the memory element NM2 in a configuration that can store data of a plurality of bits.

### 4. Further Modifications

The various technical features disclosed herein may be implemented in any manners other than as in the embodiments described above, and allow for many modifications without departure from the spirit of their technical ingenuity. That is, the embodiments described above should be understood to be in every aspect illustrative and not restrictive, and the technical scope of the present invention should be understood to be defined not by the description of the embodiments given above but by the appended claims and encompasses any modifications within a scope equivalent in significance to what is claimed.

### 5. Notes

As described above, for example, according to one aspect of the present disclosure, a non-volatile memory device (1) includes: a first current mirror (CM1); a second current mirror (CM2); a first resistor portion (R10) connected to a first MOS transistor (M1) included in the first current mirror; a second resistor portion (R2) connected to a second MOS transistor (M2) included in the second current mirror; and a sensing portion (SA) configured to sense the magnitude relationship between a first current (I1) through the first MOS transistor and a second current (I2) through the second MOS transistor. The first resistor portion includes a first memory element (NM1), which is programmable, and according to whether the first memory element is programmed, the resistance value of the first resistor portion changes. (A first configuration.)

In the first configuration described above, the first resistor portion (R10) may include: a first resistor element (R11) connected to the first MOS transistor (M1); a second resistor element (R12) connected in series with the first resistor element; and the first memory element (NM1) connected in parallel with the second resistor element. (A second configuration.)

In the first or second configuration described above, the first memory element (NM1) may store first characteristics corresponding to the relationship between the gate voltage applied to the gate of the first memory element and its on resistance as observed before the first memory element is programmed. The first memory element may store second characteristics corresponding to the relationship between the gate voltage and the on resistance as observed after the first memory element is programmed. A read operation may be executed with the gate voltage limited within a range (G0) between a first predetermined voltage (Vg1), which is the gate voltage that divides the first characteristic between regions in which the on resistance is high and low respectively, and a second predetermined voltage (Vg2), which is the gate voltage that divides the second characteristic between regions in which the on resistance is high and low respectively. (A third configuration.)

In any of the first to third configurations described above, the gate of the first memory element (NM1) can be fed with, as the gate voltage, a supply voltage, and when during the start-up of the supply voltage the gate voltage reaches a lower-limit voltage, the first and second currents start to pass. (A fourth configuration.)

The fourth configuration described above may further include: a constant current source (CI0) configured to supply the first and second current mirrors (CM1 and CM2) with a constant current (I0). When the gate voltage reaches the lower-limit voltage, the constant current source may start to supply the constant current. (A fifth configuration.)

The fourth configuration described above may further include: a second memory element (NM2) that is connected to a node to which the first and second resistor portions (R10 and R2) are connected and that is used without being programmed. The gate of the second memory element may be connected to the gate of the first memory element. (A sixth configuration.)

In the sixth configuration described above, the second memory element (NM2) may be connected to all of a plurality of sets each comprising the first and second resistor portions (R10 and R2). (A seventh configuration.)

Any of the first to seventh configurations described above may further include: a clamp circuit (2) configured to clamp the gate voltage fed to the gate of the first memory element (NM1) at an upper-limit voltage. (An eighth configuration.)

### INDUSTRIAL APPLICABILITY

The present disclosure finds applications in, for example, non-volatile memory devices employed in a variety of semiconductor devices.

### REFERENCE SIGNS LIST

1 non-volatile memory device
2 clamp circuit
10 non-volatile memory device
20 non-volatile memory device
21 amplifier
22, 23 voltage division resistor
CI0 constant current source
CM1 current mirror
CM2 current mirror
IV1-IV4 inverter
Ln1 line
Ln2 line
M0, M1, M2 transistor
Md1, Md2 data element
Md11, Md12 data element
Md21 data element
Mr1 first reference element
Mr11, Mr12 reference element
Mr2 second reference element
Mr21 reference element
NM1 memory element
NM2 memory element
PM1, PM2 PMOS transistor
R0 resistor element
R10 resistor portion
R11, R12, R2 resistor element
Rr1 first reference resistor
Rr2 second reference resistor
S1, S2 switch
S3, S4 switch
SA sense amplifier

1. A non-volatile memory device comprising:
a first current mirror;
a second current mirror;
a first resistor portion connected to a first MOS transistor included in the first current mirror;
a second resistor portion connected to a second MOS transistor included in the second current mirror; and
a sensing portion configured to sense a magnitude relationship between a first current through the first MOS transistor and a second current through the second MOS transistor,
wherein
the first resistor portion includes a first memory element, which is programmable, and according to whether the first memory element is programmed, a resistance value of the first resistor portion changes.

2. The non-volatile memory according to claim 1,
the first resistor portion includes:
a first resistor element connected to the first MOS transistor;
a second resistor element connected in series with the first resistor element; and
the first memory element connected in parallel with the second resistor element.

3. The non-volatile memory according to claim 1,
the first memory element stores first characteristics corresponding to a relationship between a gate voltage applied to a gate of the first memory element and an on resistance thereof as observed before the first memory element is programmed,
the first memory element stores second characteristics corresponding to a relationship between the gate voltage and the on resistance as observed after the first memory element is programmed, and
a read operation is executed using the gate voltage limited within a range between a first predetermined voltage, which is the gate voltage that divides the first characteristic between regions in which the on resistance is high and low respectively, and a second predetermined voltage, which is the gate voltage that divides the second characteristic between regions in which the on resistance is high and low respectively.

4. The non-volatile memory according to any one of claim 1,
a gate of the first memory element can be fed with, as a gate voltage, a supply voltage, and
when during start-up of the supply voltage the gate voltage reaches a lower-limit voltage, the first and second currents start to pass.

5. The non-volatile memory according to claim 4, further comprising:
a constant current source configured to supply the first and second current mirrors with a constant current,
wherein
when the gate voltage reaches the lower-limit voltage, the constant current source starts to supply the constant current.

6. The non-volatile memory according to claim 4, further comprising:
a second memory element connected to a node to which the first and second resistor portions are connected, the second memory element being used without being programmed,
wherein
a gate of the second memory element is connected to the gate of the first memory element.

7. The non-volatile memory according to claim 6,
the second memory element is connected to all of a plurality of sets each comprising the first and second resistor portions.

8. The non-volatile memory according to any one of claim 1, further comprising:
a clamp circuit configured to clamp a gate voltage fed to a gate of the first memory element at an upper-limit voltage.
